(19) United States
(12) Patent Application Publication
(10) Pub. No.: US 2024/0032226 A1
(43) Pub. Date: Jan. 25, 2024

(54) HINGE, FLEXIBLE DISPLAY PANEL AND ELECTRONIC DEVICE

(71) Applicant: Wuhan China Star Optoelectronics Semiconductor Display Technology Co., Ltd., Wuhan, Hubei (CN)

(72) Inventor: Guobao JIANG, Wuhan, Hubei (CN)

(73) Assignee: Wuhan China Star Optoelectronics Semiconductor Display Technology Co., Ltd., Wuhan, Hubei (CN)

(21) Appl. No.: 17/438,959

(22) PCT Filed: Aug. 10, 2021
(86) PCT No.: PCT/CN2021/111875

§ 371 Date: Jan. 12, 2023

(30) Foreign Application Priority Data
Jul. 5, 2021 (CN) 202121517617.2

(51) Int. Cl. H05K 5/02; F16C 11/04

(52) U.S. Cl. CPC H05K 5/0226; F16C 11/04

(57) ABSTRACT

A hinge, a flexible display panel, and an electronic device are disclosed. The electronic device includes a flexible display panel which includes a flexible display panel main body and a hinge. The hinge includes a first rotation mechanism, a second rotation mechanism, and a moving block. The first rotation mechanism and the second rotation mechanism are interlinked by the moving block, so that an effect of bilateral synchronous movement in the electronic device can be achieved, thereby preventing the flexible display panel main body from being pressed or pulled during folding or unfolding processes.

### FIELD OF INVENTION

The present disclosure relates to the field of display technologies, and in particular to a hinge, a flexible display panel and an electronic device.

### BACKGROUND OF INVENTION

With continuous developments of display technologies, in order to meet different usage requirements, various displays with different characteristics have emerged. A development trend of intelligence, portability, and flexibility is one of the main development directions of current electronic devices. Compared with traditional flat panel display technologies, the most prominent advantages of flexible display technologies are breaking through an inherent concept of original two-dimensional display and expanding an application field of the display technologies to more portable electronic devices. A user can fold or roll an electronic device provided with the flexible display panel as needed, so as to reduce a size of the electronic device, thereby improving portability of the electronic device.

### Technical Problems

The existing foldable electronic devices realize an effect of unfolding and folding by two rotation mechanisms disposed opposite each other in the hinge. During folding or unfolding processes of the electronic devices, since the two rotation mechanisms in the hinge cannot always rotate at the same speed, a bilateral synchronous rotation cannot be achieved in the electronic devices, resulting in a flexible display panel main body of the electronic device being pressed or pulled by the hinge, thereby reducing service lives of the electronic devices.

As mentioned above, the hinge in the existing foldable electronic devices exists a problem that the bilateral synchronous rotation cannot be achieved. Therefore, it is necessary to provide a display panel and a display device to improve this defect.

### SUMMARY OF INVENTION

### Technical Solutions

Embodiments of the present disclosure provide a hinge, a flexible display panel, and an electronic device, which are used to solve a problem that a hinge in the existing foldable electronic device cannot realize bilateral synchronous rotation.

An embodiment of the present disclosure provides a hinge, including:
a fixed support;
a first rotation mechanism including a first transmission member rotatably connected to the fixed support;
a second rotation mechanism disposed opposite the first rotation mechanism, and including a second transmission member rotatably connected to the fixed support; and
a moving block, wherein the first transmission member and the second transmission member are movably connected to the moving block, so as to convert rotation of the first transmission member and the second transmission member to linear motion of the moving block and to drive the moving block away from or close to the fixed support, and the moving block is an integrated forming structure.

According to an embodiment of the present disclosure, the first transmission member includes a first circular gear, the second transmission member includes a second circular gear, and the moving block includes a linear gear;
wherein the first circular gear and the second circular gear are meshed with the linear gear

According to an embodiment of the present disclosure, the moving block includes a base portion, the linear gear is disposed on an outside of the base portion, and the linear gear is integrally formed with the base portion.

According to an embodiment of the present disclosure, the hinge further comprises a first stopper, the first stopper is mounted on the fixed support, the first stopper and the fixed support together form a first chute, and the moving block is slidably disposed in the first chute;
wherein a wall surface of the first chute is provided with a protrusion, a groove is defined by the base portion of the moving block, and the protrusion is slidably received in the groove.

According to an embodiment of the present disclosure, the first rotation mechanism includes a first rotation member, and the second rotation mechanism includes a second rotation member;
wherein the first rotation member and the second rotation member are individually rotatably connected to the fixed support, the first circular gear surrounds the first rotation member, and the second circular gear surrounds the second rotation member.

According to an embodiment of the present disclosure, the hinge further comprises a holding mechanism, and the holding mechanism includes a first holding arm, a second holding arm, and a first holding member, wherein the first holding member is provided with a first protrusion and a second protrusion, a first groove is defined by the first holding arm, and a second groove is defined by the second holding arm;
wherein the first holding arm is fixedly connected to the first rotation member, the second holding arm is fixedly connected to the second rotation member, and the first rotation member and the second rotation member are rotatably connected to the first holding member;
in response to the hinge being in one of an unfolded state or a folded state, the first protrusion is received in the first groove, and the second protrusion is received in the second groove; in response to the hinge is in the other state of the unfolded state or the folded state, the first protrusion is separated from the first groove, and the second protrusion is separated from the second groove.

According to an embodiment of the present disclosure, the holding mechanism further includes a second holding member, the second holding member is provided with a third protrusion and a fourth protrusion, a third groove is defined by the first holding arm, and a fourth groove is defined by the second holding arm;
in response to the hinge being in one of the unfolded state or the folded state, the third protrusion is received in the third groove, and the fourth protrusion is received in the fourth groove; in response to the hinge being in the other state of the unfolded state or the folded state, the third protrusion is separated from the third groove, and the fourth protrusion is separated from the fourth groove.

According to an embodiment of the present disclosure, the holding mechanism further includes a first elastic member, a second elastic member, a third elastic member, a fourth elastic member, and a first stopper;
wherein the first elastic member and the second elastic member surround the first rotation member, the first elastic member is clamped between the first holding member and the first holding arm, the second elastic member is clamped between the second holding member and the first stopper; the third elastic member and the fourth elastic member surround the second rotation member, the third elastic member is clamped between the first holding member and the second holding arm, and the fourth elastic member is clamped between the second holding member and the first stopper.

An embodiment of the present disclosure further provides a flexible display panel, including:
a flexible display panel main body including a flexible portion and a first portion and a second portion connected to opposite ends of the flexible portion; and
a hinge, including:
a fixed support;
a first rotation mechanism including a first transmission member rotatably connected to the fixed support;
a second rotation mechanism disposed opposite the first rotation mechanism, and including a second transmission member rotatably connected to the fixed support; and
a moving block, wherein the first transmission member and the second transmission member are movably connected to the moving block, so as to convert rotation of the first transmission member and the second transmission member to linear motion of the moving block and to drive the moving block away from or close to the fixed support;
wherein the first portion is fixedly connected to the first rotation member, the second portion is fixedly connected to the second rotation member, and the moving block is located under the flexible portion.

According to an embodiment of the present disclosure, the first transmission member includes a first circular gear, the second transmission member includes a second circular gear, and the moving block includes a linear gear;
wherein the first circular gear and the second circular gear are meshed with the linear gear.

According to an embodiment of the present disclosure, the moving block includes a base portion, the linear gear is disposed on an outside of the base portion, and the linear gear is integrally formed with the base portion.

According to an embodiment of the present disclosure, the hinge further comprises a first stopper, the first stopper is mounted on the fixed support, the first stopper and the fixed support together form a first chute, and the moving block is slidably disposed in the first chute;
wherein a wall surface of the first chute is provided with a protrusion, a groove is defined by the base portion of the moving block, and the protrusion is slidably received in the groove.

According to an embodiment of the present disclosure, the first rotation mechanism includes a first rotation member, and the second rotation mechanism includes a second rotation member;
wherein the first rotation member and the second rotation member are individually rotatably connected to the fixed support, the first circular gear surrounds the first rotation member, and the second circular gear surrounds the second rotation member.

According to an embodiment of the present disclosure, the hinge further comprises a holding mechanism, and the holding mechanism includes a first holding arm, a second holding arm, and a first holding member, wherein the first holding member is provided with a first protrusion and a second protrusion, a first groove is defined by the first holding arm, and a second groove is defined by the second holding arm;
wherein the first holding arm is fixedly connected to the first rotation member, the second holding arm is fixedly connected to the second rotation member, and the first rotation member and the second rotation member are rotatably connected to the first holding member;
in response to the hinge being in one of an unfolded state or a folded state, the first protrusion is received in the first groove, and the second protrusion is received in the second groove; in response to the hinge being in the other state of the unfolded state or the folded state, the first protrusion is separated from the first groove, and the second protrusion is separated from the second groove.

According to an embodiment of the present disclosure, the holding mechanism further includes a second holding member, the second holding member is provided with a third protrusion and a fourth protrusion, a third groove is defined by the first holding arm, and a fourth groove is defined by the second holding arm;
in response to the hinge being in one of the unfolded state or the folded state, the third protrusion is received in the third groove, and the fourth protrusion is received in the fourth groove; in response to the hinge being in the other state of the unfolded state or the folded state, the third protrusion is separated from the third groove, and the fourth protrusion is separated from the fourth groove.

According to an embodiment of the present disclosure, the holding mechanism further includes a first elastic member, a second elastic member, a third elastic member, a fourth elastic member, and a second stopper;
wherein the first elastic member and the second elastic member surround the first rotation member, the first elastic member is clamped between the first holding member and the first holding arm, the second elastic member is clamped between the second holding member and the second stopper; the third elastic member and the fourth elastic member surround the second rotation member, the third elastic member is clamped between the first holding member and the second holding arm, and the fourth elastic member is clamped between the second holding member and the second stopper.

The embodiment of the present disclosure further provides an electronic device, comprising a flexible display panel, and the flexible display panel including:
a flexible display panel main body including a flexible portion and a first portion and a second portion connected to opposite ends of the flexible portion; and
a hinge, including:
a fixed support;
a first rotation mechanism including a first transmission member rotatably connected to the fixed support;
a second rotation mechanism disposed opposite the first rotation mechanism, and including a second transmission member rotatably connected to the fixed support; and
a moving block, wherein the first transmission member and the second transmission member are movably connected to the moving block, so as to convert rotation of the first transmission member and the second transmission member to linear motion of the moving block and to drive the moving block away from or close to the fixed support;
wherein the first portion is fixedly connected to the first rotation mechanism, the second portion is fixedly connected to the second rotation mechanism, and the moving block is located under the flexible portion.

According to an embodiment of the present disclosure, the first transmission member includes a first circular gear, the second transmission member includes a second circular gear, and the moving block includes a linear gear;
wherein the first circular gear and the second circular gear are meshed with the linear gear.

According to an embodiment of the present disclosure, the moving block includes a base portion, the linear gear is disposed on an outside of the base portion, and the linear gear is integrally formed with the base portion.

According to an embodiment of the present disclosure, the hinge further comprises a first stopper, the first stopper is mounted on the fixed support, the first stopper and the fixed support together form a first chute, and the moving block is slidably disposed in the first chute;
wherein a wall surface of the first chute is provided with a protrusion, a groove is defined by the base portion of the moving block, and the protrusion is slidably received in the groove.

Beneficial effect of the embodiments of the present disclosure:

The embodiments of the present disclosure provide a hinge, a flexible display panel, and an electronic device. The electronic device includes a flexible display panel which includes a flexible display panel body and a hinge. The flexible display panel body includes a flexible portion and a first portion and a second portion connected to opposite ends of the flexible portion. The hinge includes a first rotation mechanism, a second rotation mechanism, and a moving block, wherein the first rotation mechanism includes a first transmission member which is rotatably connected to a fixed support, the second rotation mechanism is disposed opposite the first rotation mechanism, and the second rotation mechanism includes a second transmission member which is rotatably connected to the fixed support. The first portion is fixedly connected to the first rotation mechanism, and the second portion is fixedly connected to the second rotation mechanism. The moving block is located under the flexible portion, and the moving block is an integral structure. The first transmission member and the second transmission member are movably connected to the moving block, so as to convert rotations of the first transmission member and the second transmission member to linear motion of the moving block, and drive the moving block away from or close to the fixed support. The first rotation mechanism and the second rotation mechanism are interlinked by the moving block, so that the first rotation mechanism and the second rotation mechanism rotate at the same speed, thereby achieving an effect of bilateral synchronous movement in the electronic device, and preventing the flexible display panel main body from being pressed or pulled during folding or unfolding processes of the electronic device.

### DESCRIPTION OF DRAWINGS

In order to illustrate technical solutions in the embodiments or in the prior art more clearly, attached drawings required for describing the embodiments or prior art will be simply explained as below. Apparently, the attached drawings for the following description are only some embodiments of the present disclosure. Those skilled in the art also could derive other attached drawings from these attached drawings without making a creative work.

FIG. 1 is a schematic diagram of the front and back structures of an electronic device provided in an embodiment of the present disclosure in an unfolded state.

FIG. 2 is a schematic structural diagram of an electronic device in a folded state according to an embodiment of the present disclosure.

FIG. 3 is a schematic exploded diagram of an electronic device provided by an embodiment of the present disclosure.

FIG. 4 is a schematic structural diagram of a hinge provided by an embodiment of the present disclosure.

FIG. 5 is a schematic exploded diagram of a hinge provided by an embodiment of the present disclosure.

FIG. 6 is a schematic structural diagram of a moving block and a fixed support provided by an embodiment of the present disclosure.

FIG. 7 is a schematic diagram of the unfolding process of the hinge provided by an embodiment of the present disclosure.

FIG. 8 is a schematic exploded diagram of a holding mechanism provided by an embodiment of the present disclosure.

FIG. 9 is a schematic diagram of structures of the first support plate and the second support plate provided by an embodiment of the present disclosure.

FIG. 10 is a schematic diagram of movements of the first support plate and the second support plate provided by an embodiment of the present disclosure.

### DETAILED DESCRIPTION OF PREFERRED EMBODIMENTS

The description of the following embodiments refers to the attached drawings to illustrate specific embodiments that can be implemented in the present disclosure. The directional terms mentioned in the present disclosure, such as “upper”, “lower”, “front”, “back”, “left”, “right”, “inner”, “outer”, and “lateral” merely refer to the directions of the attached drawings. Therefore, the directional terms are used to illustrate and understand the present disclosure, rather than to limit the present disclosure. In the drawings, units with similar structures are indicated by the same reference numerals.

The present disclosure is further described below with reference to the drawings and specific embodiments.

An embodiment of the present disclosure provides a hinge 2, a flexible display panel 100, and an electronic device 1000. The electronic device 1000 includes the flexible display panel 100 which includes the hinge 2.

In the embodiment of the present disclosure, the electronic device 1000 may be a mobile terminal, such as a smart phone, a tablet computer, a notebook computer, and the like. The electronic device 1000 may further be a wearable terminal, such as a smart watch, a smart bracelet, smart glasses, an augmented reality device, and the like. An electronic device 1000 may further be a fixed terminal, such as a desktop computer, a TV, and the like.

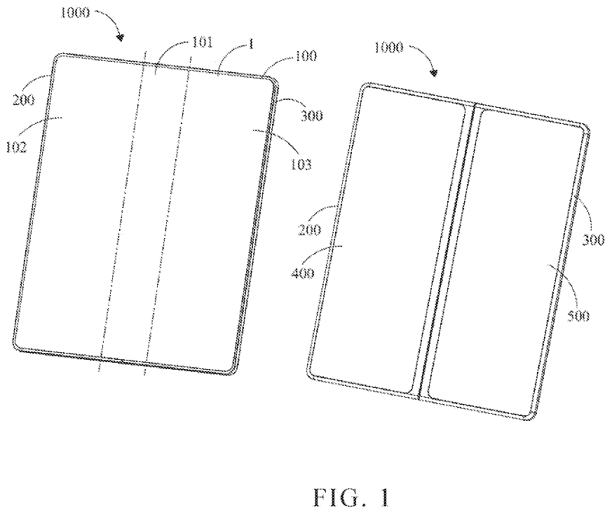

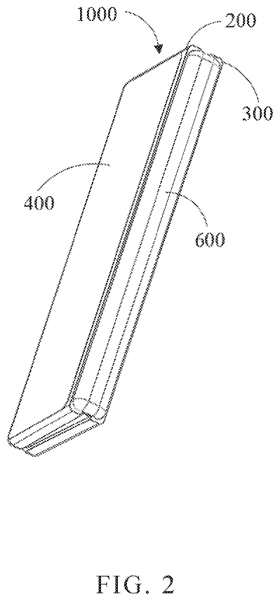

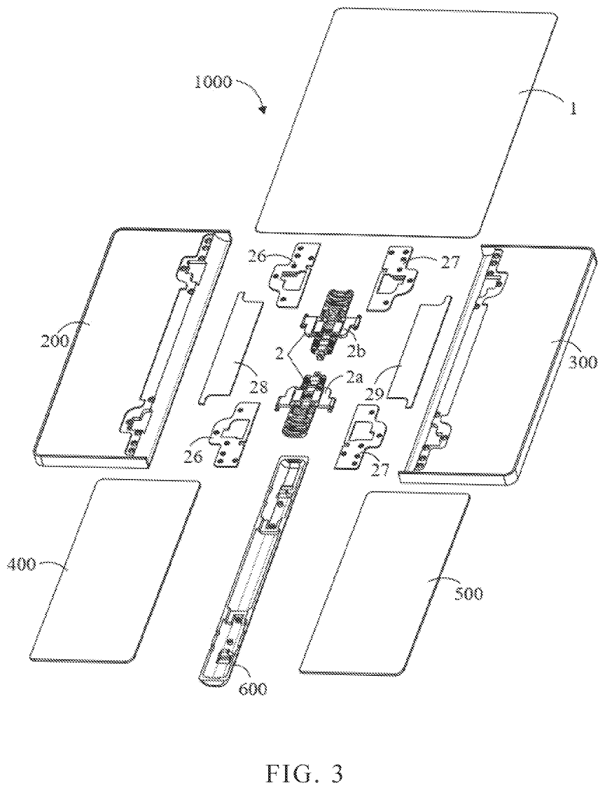

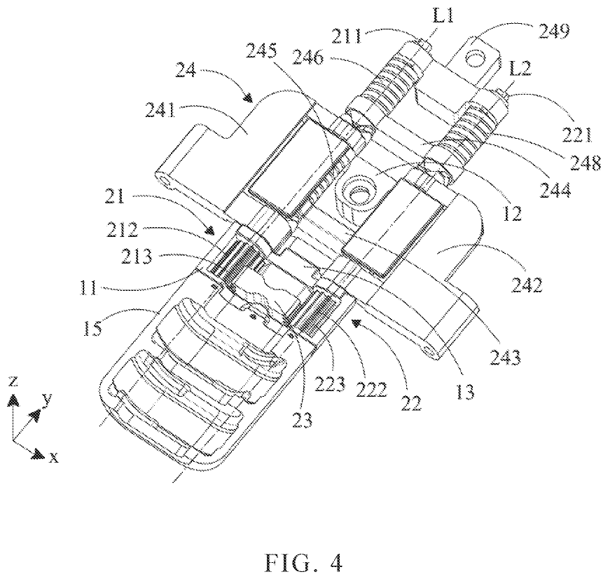

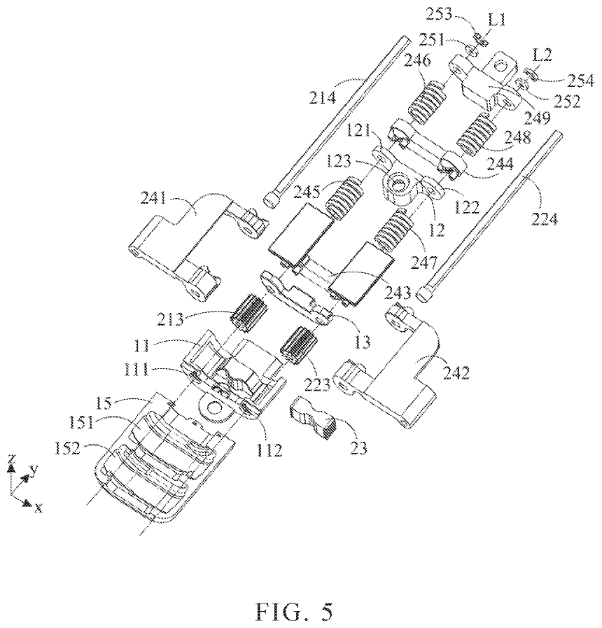

As shown in FIGS. 1 to 3, FIG. 1 is a schematic structural diagram of the front and back of the electronic device in an unfolded state provided by an embodiment of the present disclosure, FIG. 2 is a schematic structural diagram of the electronic device in a folded state provided by an embodiment of the present disclosure, and FIG. 3 is a schematic exploded diagram of an electronic device provided by an embodiment of the present disclosure. The electronic device 1000 includes a flexible display panel 100, a first housing 200, a second housing 300, a first back plate 400, and a second back plate 500, and a third housing 600.

The flexible display panel 100 includes a flexible display panel main body 1. The flexible display panel main body 1 includes a flexible portion 101 and a first portion 102 and a second portion 103 located on opposite sides of the flexible portion 101. The flexible portion 101 is a folded portion of the flexible display panel main body 1. The first portion 102 may be disposed on at least a portion of the front side of the first housing 200, and the second portion 103 may be disposed on at least a portion of the front side of the second housing 300.

The first back plate 400 is disposed on a side of the first housing 200 away from the flexible display panel 100, and the second back plate 500 is disposed on a side of the second housing 300 away from the flexible display panel 100. The first housing 200 and the second housing 300 may individually have a separate space, which can receive electronic components in the electronic device, such as a motherboard, a printed circuit board, a battery, and the like, which are required for driving the flexible display panel 100.

It should be noted that the electronic device 1000 may have at least one rotation axis for folding the electronic device 1000. In the following description, a first direction x represents a direction perpendicular to the rotation axis, a second direction y represents a direction parallel to the rotation axis, and a third direction z represents a thickness direction of the electronic device 1000. A display surface of the electronic device may be defined by the first direction x and the second direction y.

The flexible display panel 100 further includes a hinge 2 which includes a first hinge 2a and a second hinge 2b, and the first hinge 2a and the second hinge 2b are individually disposed on opposite ends of the third housing 600. The first hinge 2a and the second hinge 2b may be disposed between the first housing 200 and the second housing 300. The first hinge 2a and the second hinge 2b are both connected to the first housing 200 and the second housing 300. The first hinge 2a and the second hinge 2b may be configured to rotate the first housing 200 and the second housing 300 about two rotation axes parallel to the second direction y and are spaced in the first direction x.

In the embodiment of the present disclosure, structures of the first hinge 2a and the second hinge 2b are the same, and movement processes of the first hinge 2a and the second hinge 2b are also the same. In the following description, each schematic diagram merely takes the structure of the first hinge 2a as an example for illustration, and will not be repeated here. In practical applications, structures of the first hinge 2a and the second hinge 2b may further be different, but must be satisfied with the requirement that the first housing 200 and the second housing 300 can be rotated synchronously by the first hinge 2a and the second hinge 2b.

It should be noted that in the following description, the unfolded state may refer to the electronic device 1000 being completely unfolded, and a front side of the first housing 200 and a front side of the second housing 300 may form together a plane, so that a state of an angle of about 180 degrees is formed between the front side of the first housing 200 and the front side of the second housing 300. The folded state includes a completely folded state and a transitional folded state. The completely folded state may refer to the electronic device 1000 being completely folded. The front side of the first housing 200 and the front side of the second housing 300 may face each other, so that a state of an angle of about 0 degrees is formed between the front side of the first housing 200 and the front side of the second housing 300. The transitional folded state may refer to any transitional state between the unfolded state and the completely folded state of the electronic device 1000. The front side of the first housing 200 and the front side of the second housing 300 form together an included angle approximately greater than 0 degrees and less than 180 degrees.

The third housing 600 may be disposed between the first housing 200 and the second housing 300, and the third housing 600 may cover an outside of the hinge 2 and may protect the hinge 2.

As the electronic device 1000 is unfolded from the folded state to the unfolded state, a space between the side of the first housing 200 and the side of the second housing 300 may gradually narrow, and an opposite side of the third housing 600 may be inserted into the first housing 200 and the second housing 300. In response to the electronic device 1000 being in an unfolded state, the third housing 600 may be covered by the first back plate 400 and the second back plate 500, and will not be exposed to the outside.

As the electronic device 1000 is folded from the unfolded state to the folded state, the space between the side of the first housing 200 and the side of the second housing 300 may gradually widen, and the third housing 600 may be gradually exposed by the first housing 200 and the second housing 300 are. In response to the electronic device 1000 being in a completely folded state, at least a portion of the third housing 600 may be exposed to the outside between the side of the first housing 200 and the side of the second housing 300, and the first back plate 400 and the second back plate 500 can still cover some remaining portions of the third housing 600.

Refer to FIGS. 3 and 4. FIG. 4 is a schematic structural diagram of the hinge provided by an embodiment of the present disclosure. It should be noted that in the embodiment of the present disclosure, the structures of the first hinge 2a and the second hinge 2b are the same. In FIG. 4, only the first hinge 2a is taken as an example for illustration. Both the first hinge 2a and the second hinge 2b include a fixed support 10, a first rotation mechanism 21, a second rotation mechanism 22, and a moving block 23.

The first rotation mechanism 21 and the second rotation mechanism 22 are individually movably connected to the fixed support 10, and the first rotation mechanism 21 is disposed opposite the second rotation mechanism 22. The first portion 102 of the flexible display panel body 1 is fixedly connected to the first rotation mechanism 21, and the second portion 103 is fixedly connected to the second rotation mechanism 22. The rotation axes include a first axis L1 and a second axis L2, and the first axis L1 and the second axis L2 are parallel to the second direction y and are spaced in the first direction x. The first rotation mechanism 21 can rotate about the first axis L1, and the second rotation mechanism 22 can rotate about the second axis L2. In the embodiment of the present disclosure, the structures of the first rotation mechanism 21 and the second rotation mechanism 22 are the same. In practical applications, the structures of the first rotation mechanism 21 and the second rotation mechanism 22 may be the same or different, and are not limited thereto.

The moving block 23 is movably connected to the first rotation mechanism 21 and the second rotation mechanism 22, and is located under the flexible portion 101 of the flexible display panel main body 1. During the folded or unfolded process of the electronic device 1000, the moving block 23 merely moves along the third direction z or a reverse movement opposite the third direction z, so that the first rotation mechanism 21 and the second rotation mechanism 22 can maintain a synchronous movement.

The first rotation mechanism 21 includes a first rotation member 211 and a first transmission member 212, and the first transmission member 212 is rotatably connected to the fixed support 10. The second rotation mechanism 22 includes a second transmission member 222, and the second transmission member 222 is rotatably connected to the fixed support 10. The first transmission member 212 and the second transmission member 222 are movably connected to the moving block 23, so as to convert rotation of the first transmission member 212 and the second transmission member 222 to linear movement of the moving block 23, and drive the moving block 23 away from or close to the fixed support 10. The moving block 23 is an integral structure.

In the embodiment of the present disclosure, the first transmission member 212 and the second transmission member 222 individually rotate in opposite directions around the first axis L1 and the second axis L2. A linear motion of the moving block 23 is driven by the first transmission member 212 and the second transmission member 222. A direction in which the moving block 23 moves in a straight line is parallel to the third direction z.

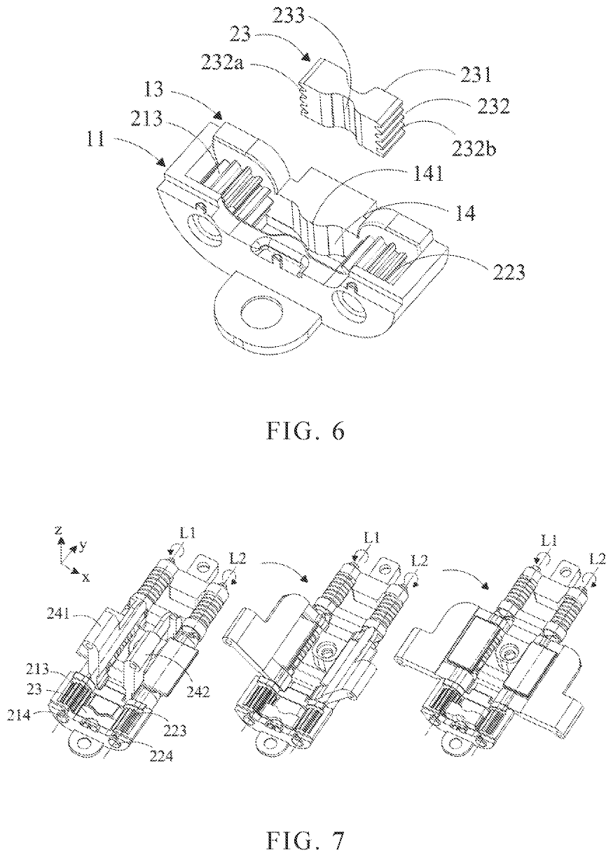

Refer to FIGS. 4 to 6. FIG. 5 is a schematic exploded view of a hinge provided by an embodiment of the present disclosure, and FIG. 6 is a structural schematic view of a moving block and a fixed support provided by an embodiment of the present disclosure. The first rotation mechanism 21 includes a first rotation member 211, and the second rotation mechanism 22 includes a second rotation member 221. The first rotation member 211 and the second rotation member 221 are individually rotatably connected to the fixed support 10. The first transmission member 212 includes a first circular gear 213 which surrounds the first rotation member 211, and the second transmission member 222 includes a second circular gear 223 which surrounds the second rotation member 221.

The fixed support 10 includes a first fixed support 11. A first shaft hole 111 and a second shaft hole 112 is defined by the first fixed support 11, and the first shaft hole 111 and a second shaft hole 112 are spaced in the first direction x. The first rotation member 211 includes a first rotation shaft 214. An axis of the first rotation shaft 214 coincides with the first axis L1. The first rotation shaft 214 passes through the first shaft hole 111, and can rotate relative to the first fixed support 11. The first circular gear 213 surrounds the first rotation shaft 214 along the first axis L1, and is fixedly connected to the first rotation shaft 214.

The second rotation member 221 includes a second rotation shaft 224. An axis of the second rotation shaft 224 coincides with the second axis L2. The second rotation shaft 224 passes through the second shaft hole 112, and can rotate relative to the first fixed support 11. The second circular gear 223 surrounds the second rotation shaft 224 along the second axis L2, and is fixedly connected to the second rotation shaft 224.

The fixed connection mode of the first circular gear 213 and the first rotation shaft 214 and the fixed connection mode of the second circular gear 223 and the second rotation shaft 224 include, but are not limited to, key connection or interference fit connection.

As shown in FIG. 6, the moving block 23 includes a base portion 231 and a linear gear 232 disposed on the outside of the base portion 231. The linear gear 232 includes a first linear gear 232a and a second linear gear 232b. The first linear gear 232a and the second linear gear 232b are located on opposite sides of the base portion 231. The first gear 213 meshes with the first linear gear 232a, and the second gear 223 meshes with the second linear gear 232b.

Preferably, the base portion 231 and the linear gear 232 are integrally formed, so that a number of parts in the hinge 2 can be reduced, thereby reducing difficulty in assembly of the hinge 2. In practical applications, the base portion 231 and the linear gear 232 may further be two independent components, and the linear gear 232 may be fixedly connected to the base portion 231 by including, but not limited to, gluing, snapping, or threaded connection.

Refer to FIGS. 4 and 5. Both the first hinge 2a and the second hinge 2b individually include a holding mechanism 24 which includes a first holding arm 241 and a second holding arm 242. The first holding arm 241 surrounds the first rotation shaft 214 and is fixedly connected to the first rotation shaft 214. The second holding arm 242 surrounds the second rotation shaft 224 and is fixedly connected to the second rotation shaft 224.

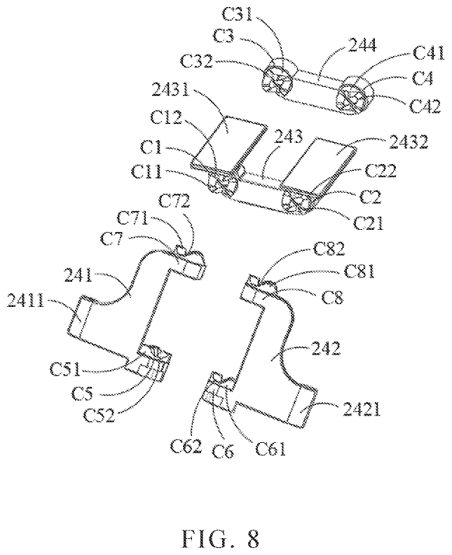

Refer to FIG. 7. FIG. 7 is a schematic diagram of the unfolded process of the hinge provided by an embodiment of the present disclosure. From left to right, the hinge is unfolded from a completely folded state to an unfolded state, and the folding or unfolding process of the hinge is reversible. From right to left, it can be seen that the hinge is folded from the unfolded state to the completely folded state.

During the unfolding process of the hinge, the first holding arm 241 drives the first rotation shaft 214 to rotate around the first axis L1 in a direction indicated by an arrow, and the first circular gear 213 follows the first rotation shaft 214 to rotate in the same direction. The second holding arm 242 drives the second rotation shaft 224 to rotate around the second axis L2 in a direction indicated by an arrow, and the second circular gear 223 follows the second rotation shaft 224 to rotate in the same direction. The moving block 23 moves along the third direction z under a meshing action of the circular gear and the linear gear, and gradually moves away from the fixed support 10.

During the folding process of the hinge, the first holding arm 241 drives the first rotation shaft 214 to rotate around the first axis L1 in a direction opposite a direction indicated by the arrow, and the first circular gear 213 follows the first rotation shaft 214 to rotate in the same direction. The second holding arm 242 drives the second rotation shaft 224 to rotate around the second axis L2 in a direction opposite a direction indicated by the arrow, and the second circular gear 223 follows the second rotation shaft 224 to rotate in the same direction. The moving block 23 moves along a direction opposite the third direction z under the meshing action of the circular gear and the linear gear, and gradually approaches the fixed support 10.

During the unfolding or folding process of the hinge, the moving block 23 always moves along the third direction z or the direction opposite the third direction z. A meshing speed of the first circular gear 213 and the first linear gear 232a is the same as a meshing speed of the second circular gear 223 and the second linear gear 232b, so that rotation speeds of the first circular gear 213 and the second circular gear 223 are the same, thereby realizing an effect of a synchronous rotation of the first rotation mechanism 21 and the second rotation mechanism 22.

The fixed support 10 further includes a fixed block 12 which includes a body portion 120 and a first connection portion 121 and a second connection portion 122, which extend from opposite sides of the body portion 120. The first rotation member 211 passes through the first connection portion, and the second rotation member 221 passes through the second connection portion 122. A through hole 123 is defined by the main body 120. The through hole 123 penetrates the main body 120 in the third direction z, and is used to fix the fixed block 12 to the third housing 600 by screws.

Shaft holes are defined by both the first connection portion 121 and the second connection portion 122. The first rotation shaft 214 passes through a shaft hole of the first connection portion 121, and can rotate relative to the fixed block 12. The second rotation shaft 224 passes through a shaft hole of the second connection portion 122, and can rotate relative to the fixed block 12.

The hinge further includes a first stopper 13 mounted on the fixed support 10. The first stopper 13 and the fixed support 10 enclose a first chute 14, and the moving block 23 is slidably disposed in the first chute 14.

As shown in FIG. 6, the first stopper 13 has two connection portions protruding from a body of the first stopper 13 along the first direction x, and shaft holes are individually defined by the two connection portions. The first rotation shaft 214 and the second rotation shaft 224 individually pass through the shaft holes, and can rotate relative to the first stopper 13.

The first stopper 13 is fastened on the first fixed support 11, and the first stopper and the first fixed support 11 enclose the first chute 14. The moving block 23 is slidably disposed in the first chute 14, and can only move in the third direction z or a direction opposite the third direction z in the first chute 14, thereby ensuring that the first circular gear 213 and the second circular gear 223 can rotate synchronously at the same rotation speed, and further preventing the moving block 23 from being stuck in the first chute 14 during a process of sliding.

Further, a protrusion 141 is provided on a wall surface of the first chute 14, a groove 233 is defined by the base portion 231 of the moving block 23, and the protrusion 141 is slidably received in the groove 233.

As shown in FIG. 6, a side of the first fixed support 11 and a side of the first stopper 13 facing each other are individually provided with protrusions 141, and grooves 233 are individually defined by opposite sides of the base portion 231 of the moving block 23. The protrusion 141 is slidably received in the corresponding groove 233. In this way, a movement direction of the moving block 23 is further limited by the cooperation of the protrusion 141 and the groove 233, preventing the moving block 23 from being deflected left and right, thereby reducing a virtual position of the moving block 23 matched with the first chute 14, and increasing stability of the moving block 23 during moving process.

In practical applications, a number of the grooves 233 defined by the moving block 23 and a number of the protrusions 141 on the wall surface of the first chute 14 can be determined according to a size of the moving block 23 and a size of the first chute 14. The larger the sizes of the moving block 23 and the first chute 14 are, the more the numbers of the grooves 233 and the protrusions 141 required are. The number of the grooves 233 defined by the moving block 23 and the number of the protrusions 141 on the wall surface of the first chute 14 can be determined according to actual situations, and may be 1, 2, 3, or more, etc., and is not limited here.

The holding mechanism 24 further includes a first holding member 243 which is provided with a first protrusion C11 and a second protrusion C21. A first groove C52 is defined by the first holding arm 241, and a second groove C62 is defined by the second holding arm 242. The first holding arm 241 is connected to the first rotation member 211, the second holding arm 242 is connected to the second rotation member 221, and the first rotation member 211 and the second rotation member 221 are rotatably connected to the first holding member 243. In response to the hinge being in one of the folded state or the unfolded state, the first protrusion C11 is received in the first groove C52, and the second protrusion C21 is received in the second groove C62. In response to the flexible portion 101 being in the other state of the folded state or the unfolded state, the first protrusion C11 is separated from the first groove C52, and the second protrusion C21 is separated from the second groove C62.

In one embodiment, with reference to FIGS. 4, 5, and 8, FIG. 8 is a schematic exploded view of the holding mechanism provided by an embodiment of the present disclosure. The first holding member 243 is provided with a first cam C1 and a second cam C2, which protrude from a main body of the first holding member 243, wherein the first cam C1 may include a plurality of first protrusions C11 which protrude from an edge of the first cam C1 in the second direction y. A fifth groove C12 is defined between the adjacent first protrusions C11. The first rotation shaft 214 passes through the first cam C1, and can rotate relative to the first cam C1. The second cam C2 may include a plurality of second protrusions C21 which protrude from an edge of the second cam C2 in the second direction y. A sixth groove C22 is defined between the adjacent second protrusions C21. The first rotation shaft 214 passes through the second cam C2, and can rotate relative to the second cam C2.

The first holding arm 241 includes a fifth cam C5 protruding from a body of the first holding arm 241 in the first direction x, and the fifth cam C5 may include a plurality of fifth protrusions C51 protruding from an edge of the fifth cam C5 in the second direction y. A first groove C52 is defined between the adjacent fifth protrusions C51, and the first rotation shaft 214 passes through the fifth cam C5. The second holding arm 242 includes a sixth cam C6 protruding from a body of the second holding arm 242 in the first direction x. The sixth cam C6 may include a plurality of sixth protrusions C61 protruding from an edge of the sixth cam C6 in the second direction y, and a second groove C62 is defined between the adjacent sixth protrusions C61. A second rotation shaft 224 passes through the sixth cam C6.

The holding mechanism 24 further includes a second holding member 244 which is provided with a third protrusion C31 and a fourth protrusion C41. A third groove C72 is defined by the first holding arm 241, and a fourth groove C82 is defined by the second holding arm 242. In response to the flexible portion being in one of the unfolded state or the folded state, the third protrusion C31 is received in the third groove C72, and the fourth protrusion C41 is received in the fourth groove C82. In response to the flexible portion being in the other state of the unfolded state or the folded state, the third protrusion C31 is separated from the third groove C72, and the fourth protrusion C41 is separated from the fourth groove C82.

The second holding member 244 is provided with a third cam C3 and a fourth cam C4, which protrude from a main body of the second holding member 244, and the third cam C3 may include a plurality of third protrusions C31 protruding from an edge of the third cam C3 in the second direction y. A seventh groove C32 is defined between the adjacent third protrusions C31. The first rotation shaft 214 passes through the third cam C3, and can rotate relative to the third cam C3. The fourth cam C4 may include a plurality of fourth protrusions C41 protruding from an edge of the fourth cam C4 in the second direction y. An eighth groove C42 is defined between the adjacent fourth protrusions C41. The first rotation shaft 214 passes through the fourth cam C4, and can rotate relative to the fourth cam C4.

The first holding arm 241 includes a seventh cam C7 protruding from the body of the first holding arm 241 in the first direction x, and the seventh cam C7 may include a plurality of seventh protrusions protruding from an edge of the seventh cam C7 in the second direction y. A third groove C72 is defined between the adjacent seventh protrusions C71, and the first rotation shaft 214 passes through the seventh cam C7. The second holding arm 242 includes an eighth cam C8 protruding from the body of the second holding arm 242 in the first direction x, and the eighth cam C8 may include a plurality of eighth protrusions C81 protruding from an edge of the eighth cam C8 in the second direction y. A fourth groove C82 is defined between the adjacent eighth protrusions C81, and the second rotation shaft 224 passes through the eighth cam C8.

Each of the first protrusions C11 to the eighth protrusions C81 has a flat end which has a sliding surface. The sliding surface is an engagement surface of the two inclined side surfaces of each protrusion.

The holding mechanism 24 further includes a first elastic member 245, a second elastic member 246, a third elastic member 247, a fourth elastic member 248, and a second stopper 249. The first elastic member 245, the second elastic member 246, the third elastic member 247, and the fourth elastic member 248 are both springs. The second stopper 249 includes a third connection portion and a fourth connection portion protruding from both sides of a main body of the second stopper 249 in the first direction x, and shaft holes are individually defined by both the third connection portion and the fourth connection portion. The first rotation shaft 214 passes through the third connection portion, and the second rotation shaft 224 passes through the fourth connection portion.

The first elastic member 245 and the second elastic member 246 surround the first rotation member 211. The first elastic member 245 is clamped between the first holding member 243 and the first holding arm 241. A first connection portion of the fixed block 12 is located between the fifth cam C5 of the first holding arm 241 and the first elastic member 245. The second elastic member 246 is clamped between the second holding member 244 and the third connection portion of the second stopper 249. The third elastic member 247 and the fourth elastic member 248 surround the second rotation member 221. The third elastic member 247 is clamped between the first holding member 243 and the second holding arm 242. A second connection portion of the fixed block 12 is located between the sixth cam C6 of the second holding arm 242 and the second elastic member 246. The fourth elastic member 248 is clamped between the second holding member 244 and the fourth connection portion of the second stopper 249.

In response to the electronic device 1000 being in a unfolded state or a completely folded state, the hinge is in an unfolded state or a completely folded state, the flexible portion 101 is in a unfolded state or a completely folded state, the first cam C1 of the first holding member 243 is ordinarily engaged with the fifth cam C5 of the first holding arm 241, the second cam C2 of the first holding member 243 is ordinarily engaged with the sixth cam C6 of the second holding arm 242, the third cam C3 of the second holding member 244 is ordinarily engaged with the seventh cam C7 of the first holding arm 241, and the fourth cam C4 of the second holding member 244 is ordinarily engaged with the eighth cam C8 of the second holding arm 242.

The ordinary engagement means that, for example, the first protrusion C11 of the first cam C1 is received in the first groove C52 of the fifth cam C5; the fifth protrusion C51 is received in the fifth groove C12; the second protrusion C21 of the second cam C2 is received in the second groove C62 of the sixth cam C6; the sixth protrusion C61 is received in the sixth groove C22; the third protrusion C31 of the third cam C3 is received in the third groove C72 of the seventh cam C7; the seventh protrusion C71 is received in the seventh groove C32; the fourth protrusion C41 of the fourth cam C4 is received in the fourth groove C82 of the eighth cam C8; and the eighth protrusion C81 is received in the eighth groove C42.

In response to the electronic device 1000 being in the transitional folded state, the hinge is in the transitional folded state, the flexible portion 101 is in the folded state, the first cam C1 of the first holding member 243 is in open engagement with the fifth cam C5 of the first holding arm 241; the second cam C2 of the first holding member 243 is in open engagement with the sixth cam C6 of the second holding arm 242; the third cam C3 of the second holding member 244 is in open engagement with the seventh cam C7 of the first holding arm 241; and the fourth cam C4 of the second holding member 244 is in open engagement with the eighth cam C8 of the second holding arm 242.

The open engagement means that, for example, the first protrusion C11 of the first cam C1 is disengaged from the first groove C52 of the fifth cam C5, and a sliding surface of the first protrusion C11 is in contact with a sliding surface of the fifth protrusion C51; the second protrusion C21 of the second cam C2 is disengaged from the second groove C62 of the sixth cam C6, and a sliding surface of the second protrusion C21 is in contact with a sliding surface of the sixth protrusion C61; the third protrusion C31 of the third cam C3 is disengaged from the third groove C72 of the seventh cam C7, and a sliding surface of the third protrusion C31 is in contact with a sliding surface of the seventh protrusion C71; and the fourth protrusion C41 of the fourth cam C4 is disengaged from the fourth groove C82 of the eighth cam C8, and a sliding surface of the fourth protrusion C41 is in contact with a sliding surface of the eighth protrusion C81.

During the process of the electronic device 1000 being folded from the unfolded state to the transitional folded state, the first holding arm 241 rotates clockwise about the first axis L1, the second holding arm 242 rotates counterclockwise about the second axis L2, and the cams engaged with each other gradually changes from the ordinary engagement to the open engagement, where the first protrusion C11 is gradually disengaged from the first groove C52, the second protrusion C21 is gradually disengaged from the second groove C62, the third protrusion C31 is gradually disengaged from the third groove C72, and the fourth protrusion C41 is gradually disengaged from the fourth groove C82. The first elastic member 245 to the fourth elastic member 248 are compressed by the corresponding holding members, resulting in a gradual increase in an amount of elastic deformation. In response to an angle between the first portion 102 and the second portion 103 ranging from 0° to 30°, under an action of the compressing force of each of the elastic members and a pressure angle of each of the cams, the electronic device 1000 can be restored to an unfolded state without external force.

In response to the electronic device 1000 being in a transitional folded state, the plurality of cams engaged with each other are in the open engagement, and the pressure angle of each of the cams is 0°, the angle between the first portion 102 and the second portion 103 may be maintained at to 150°, and the elastic deformation amount of each of the elastic member remains unchanged, so that the electronic device 1000 can be maintained in a transitional folded state without external force.

During the electronic device 1000 being folded from the transitional folded state to the completely folded state, the plurality of cams engaged with each other gradually changes from the open engagement to the ordinary engagement. The first protrusion C11 is gradually received in the first groove C52, the second protrusion C21 is gradually received in the second groove C62, the third protrusion C31 is gradually received in the third groove C72, and the fourth protrusion C41 is gradually received in the fourth groove C82. The elastic deformation of each of the elastic members gradually decreases. In response to the angle between the first portion 102 and the second portion 103 of the display panel body ranging from 150° to 180°, under the action of the compressing force of each of the elastic members and the pressure angle of the cams, the electronic device 1000 can automatically be folded from the transitional folded state to the completely folded state without external force.

In practical applications, a number of the holding members in the holding mechanism 24 is not limited to 1 or 2 mentioned in the above embodiments, but may also be 3, 4, or more. A number of the elastic members needs to meet the number of the holding members. The larger the size of the electronic device is, the greater the number of the holding members required is.

Further, the first holding member 243 has a first fixed support plate 2431 and a second fixed support plate 2432. The first fixed support plate 2431 is located on the first cam C1, and the second fixed support plate 2432 is located on the second cam C2. The first fixed support plate 2431 and the second fixed support plate 2432 are integrally formed. The first cam C1, the second cam C2, and the main body portion of the first holding member 243 are integrally formed. In response to the hinge being in the unfolded state, the first fixed support plate 2431 and the second fixed support plate 2432 can be used to support the flexible portion 101 of the flexible display panel main body 1, so as to reduce a crease of the flexible portion 101.

In an embodiment, as shown in FIGS. 4 and 5, the first hinge 2a and the second hinge 2b further include a first limiting piece 251, a second limiting piece 252, a first fixing clip 253, and a second fixing clip 254. The first limiting piece 251 and the first fixing clip 253 sequentially surround one end of the first rotation shaft 214 passing through the second stopper 249, and the second limiting piece 252 and the second fixing clip 254 sequentially surround one end of the second rotation shaft 224 passing through the second stopper 249.

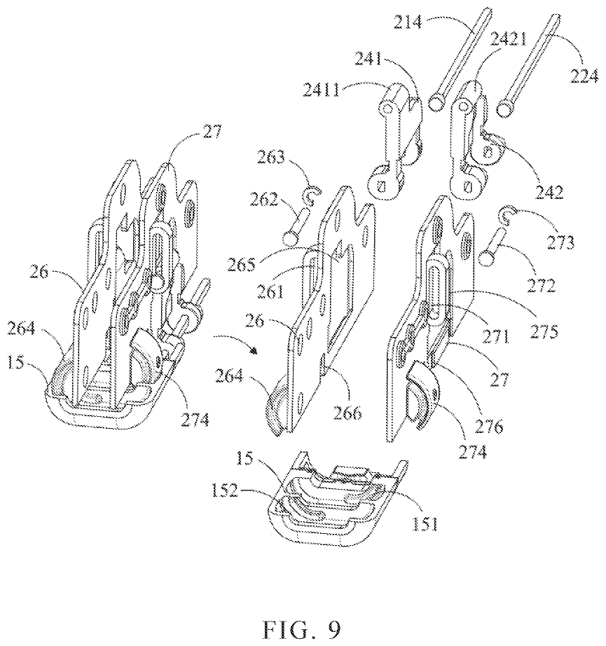

Refer to FIG. 9. FIG. 9 is a schematic diagram of structures of a first support plate and a second support plate provided by an embodiment of the present disclosure. Each of the first hinge 2a and the second hinge 2b includes a first support plate 26 and a second support plate 27. The first support plate 26 is connected to the first holding arm 241, so as to move under driving of the first holding arm 241, and the second support plate 27 is connected to the second holding arm 242, so as to move under driving of the second holding arm 242. The first support plate 26 is fixedly connected to a front side of the first housing 200 by screws. The first support plate 26 can be used to support the first portion 102. The second support plate 27 is fixedly connected to a front side of the second housing 300 by screws. The second support plate 27 can be used to support the second portion 103.

A second chute 261 is defined by the first support plate 26, a third chute 271 is defined by the second support plate 27, and both the second chute 261 and the third chute 271 are linear chutes. The first holding arm 241 includes a fifth connection portion 2411, the second holding arm 242 includes a sixth connection portion 2421, and shaft holes are individually defined by both the fifth connection portion 2411 and the sixth connection portion 2421.

The hinge further includes a first fixing member 262, a second fixing member 272, a third fixing clip 263, and a fourth fixing clip 273. Both the first fixing member 262 and the second fixing member 272 are pin shafts. The first fixing member 262 passes through the shaft holes of the second chute 261 and the fifth connection portion 2411, and is fixedly connected to the first holding arm 241. A third fixing clip 263 surrounds one end of the first fixing member 262 passing through the fifth connection portion 2411, and the first fixing member 262 can slide and rotate relative to the second chute 261. The second fixing member 272 passes through the shaft holes of the third chute 271 and the sixth connection portion 2421, and is fixedly connected to the second holding arm 242. A fourth fixing clip 273 surrounds one end of the second fixing member 272 passing through the sixth connection portion 2421, and the second fixing member 272 can slide and rotate relative to the third chute 271.

The first support plate 26 is provided with a first sliding block 264, and the second support plate 27 is provided with a second sliding block 274. The fixed support 10 includes a second fixed support 15 which is fixedly connected to the first fixed support 11. A fourth chute 151 and a fifth chute 152 are defined by the second fixed support 15, the first sliding block 264 is slidably disposed in the fourth chute 151, and the second sliding block 274 is slidably disposed in the fifth chute 152. The first sliding block 264 is integrally formed with a body of the first support plate 26, and the second sliding block 274 is integrally formed with a body of the second support plate 27. In practical applications, the first sliding block 264 and the first support plate 26 may be two independent components, and the first sliding block 264 and the first support plate 26 may be fixedly connected by screwing or snapping. The second sliding block 274 and the second support plate 27 may be two independent components, and the second sliding block 274 and the second support plate 27 may be fixedly connected by screwing or snapping.

A position of the first fixing member 262 in the second chute 261 where the hinge is in the unfolded state is different from a position of the first fixing member 262 in the second chute 261 where the hinge is in the folded state. A position of the second fixing member 272 in the third chute 271 where the hinge is in the unfolded state is different from a position of the second fixing member 272 in the third chute 271 where the hinge is in the folded state.

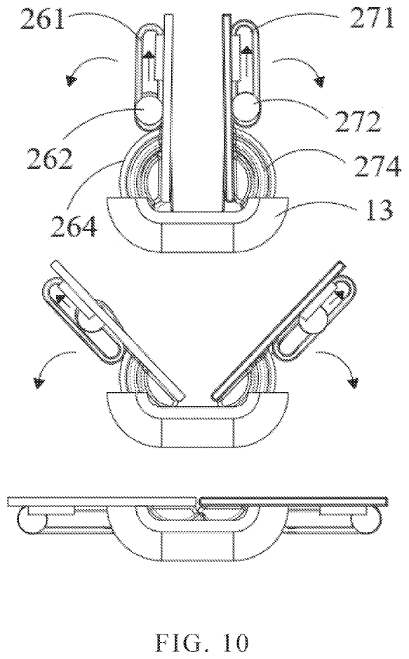

Refer to FIG. 10. FIG. 10 is a schematic diagram of movements of the first support plate and the second support plate provided by an embodiment of the present disclosure. In response to the electronic device 1000 being in a completely folded state, the first fixing member 262 is located on one end of the second chute 261 close to the second fixed support 15, and the second fixing member 272 is located at one end of the third chute 271 close to the second fixed support 15.

During a process of the electronic device 1000 being unfolded from the completely folded state to the unfolded state, the first support plate 26 and the second support plate 27 rotate opposite to each other in a direction of an arrow as shown in the figure. During the process of the first support plate 26 rotating in the direction of the arrow as shown in the figure, the first fixing member 262 drives the first holding arm 241 to rotate in the same direction, slides in the second chute 261 in the direction of the arrow as shown in the figure, and gradually moves away from the second fixed support 15. During the process of the support plate 27 rotating in the direction of the arrow as shown in the figure, the second fixing member 272 drives the second holding arm 242 to rotate in the same direction, slides in the third chute 271 in the direction of the arrow as shown in the figure, and gradually moves away from the second fixed support 15.

In response to the electronic device 1000 being in the unfolded state, the flexible portion 101 is in an unfolded state, the first fixing member 262 is located on one end of the second chute 261 away from the second fixed support 15, and the second fixing member 272 is located on one end of the third chute 271 away from the second fixed support 15.

A first avoidance opening 265 and a second avoidance opening 266 are defined by the first support plate 26, and a third avoidance opening 275 and a fourth avoidance opening 276 are defined by the second support plate 27. In response to the electronic device 1000 being in a unfolded state, the first avoidance opening 265 exposes the main body portion of the first holding arm 241 and the first fixed support plate 2431 of the first holding member 243; the second avoidance opening 266 exposes a part of the moving block 23; the third avoidance opening 275 exposes the main portion of the second holding arm 242 and the second fixed support plate 2432 of the first holding member 243; and the fourth avoidance opening 276 exposes the remaining part of the moving block 23, thereby preventing the first support plate 26 and the second support plate 27 from blocking the movements of the first holding arm 241, the second holding arm 242, and the moving block 23.

In an embodiment, as shown in FIG. 3, the hinge further includes a third support plate 28 and a fourth support plate 29. The third support plate 28 is fixedly connected to the front side of the first housing 200 by screws, the third support plate 28 and the first support plate 26 are on the same plane, and are used to support the first portion 102. The fourth support plate 29 and the second housing 300 are fixedly connected by screws, the fourth support plate 29 and the second support plate 27 are on the same plane, and are used to support the second portion 103.

### Beneficial Effect of the Embodiments of the Present Disclosure

The embodiments of the present disclosure provide a hinge, a flexible display panel, and an electronic device. The electronic device includes a flexible display panel which includes a flexible display panel body and a hinge. The flexible display panel body includes a flexible portion and a first portion and a second portion connected to opposite ends of the flexible portion. The hinge includes a first rotation mechanism, a second rotation mechanism, and a moving block, wherein the first rotation mechanism includes a first transmission member which is rotatably connected to a fixed support, the second rotation mechanism is disposed opposite the first rotation mechanism, and the second rotation mechanism includes a second transmission member which is rotatably connected to the fixed support. The first portion is fixedly connected to the first rotation mechanism, and the second portion is fixedly connected to the second rotation mechanism. The moving block is located under the flexible portion, and the moving block is an integral structure. The first transmission member and the second transmission member are movably connected to the moving block, so as to convert rotations of the first transmission member and the second transmission member to linear motion of the moving block, and drive the moving block away from or close to the fixed support. The first rotation mechanism and the second rotation mechanism are interlinked by the moving block, so that the first rotation mechanism and the second rotation mechanism rotate at the same speed, thereby achieving an effect of bilateral synchronous movement in the electronic device, and preventing the flexible display panel main body from being pressed or pulled during folding or unfolding processes of the electronic device.

In summary, although the preferred embodiments of the present disclosure are disclosed as above, the above preferred embodiments are not intended to limit the present disclosure. Those skilled in the art can make various changes and modifications without departing from the spirit and scope of the present disclosure. Therefore, the protection scope of the present disclosure is subject to the appended claims.

What is claimed is:

1. A hinge, comprising:
a fixed support;
a first rotation mechanism including a first transmission member rotatably connected to the fixed support;
a second rotation mechanism disposed opposite the first rotation mechanism, and including a second transmission member rotatably connected to the fixed support; and
a moving block, wherein the first transmission member and the second transmission member are movably connected to the moving block, so as to convert rotation of the first transmission member and the second transmission member to linear motion of the moving block and to drive the moving block away from or close to the fixed support.

2. The hinge of claim 1, wherein the first transmission member includes a first circular gear, the second transmission member includes a second circular gear, and the moving block includes a linear gear;
wherein the first circular gear and the second circular gear are meshed with the linear gear.

3. The hinge of claim 2, wherein the moving block includes a base portion, the linear gear is disposed on an outside of the base portion, and the linear gear is integrally formed with the base portion.

4. The hinge of claim 3, wherein the hinge further comprises a first stopper, the first stopper is mounted on the fixed support, the first stopper and the fixed support together form a first chute, and the moving block is slidably disposed in the first chute;
wherein a wall surface of the first chute is provided with a protrusion, a groove is defined by the base portion of the moving block, and the protrusion is slidably received in the groove.

5. The hinge of claim 2, wherein the first rotation mechanism includes a first rotation member, and the second rotation mechanism includes a second rotation member;
wherein the first rotation member and the second rotation member are individually rotatably connected to the fixed support, the first circular gear surrounds the first rotation member, and the second circular gear surrounds the second rotation member.

6. The hinge of claim 5, wherein the hinge further comprises a holding mechanism, and the holding mechanism includes a first holding arm, a second holding arm, and a first holding member, wherein the first holding member is provided with a first protrusion and a second protrusion, a first groove is defined by the first holding arm, and a second groove is defined by the second holding arm;
wherein the first holding arm is fixedly connected to the first rotation member, the second holding arm is fixedly connected to the second rotation member, and the first rotation member and the second rotation member are rotatably connected to the first holding member;
in response to the hinge being in one of an unfolded state or a folded state, the first protrusion is received in the first groove, and the second protrusion is received in the second groove; in response to the hinge is in the other state of the unfolded state or the folded state, the first protrusion is separated from the first groove, and the second protrusion is separated from the second groove.

7. The hinge of claim 6, wherein the holding mechanism further includes a second holding member, the second holding member is provided with a third protrusion and a fourth protrusion, a third groove is defined by the first holding arm, and a fourth groove is defined by the second holding arm;
in response to the hinge being in one of the unfolded state or the folded state, the third protrusion is received in the third groove, and the fourth protrusion is received in the fourth groove; in response to the hinge being in the other state of the unfolded state or the folded state, the third protrusion is separated from the third groove, and the fourth protrusion is separated from the fourth groove.

8. The hinge of claim 7, wherein the holding mechanism further includes a first elastic member, a second elastic member, a third elastic member, a fourth elastic member, and a second stopper;
wherein the first elastic member and the second elastic member surround the first rotation member, the first elastic member is clamped between the first holding member and the first holding arm, the second elastic member is clamped between the second holding member and the second stopper; the third elastic member and the fourth elastic member surround the second rotation member, the third elastic member is clamped between the first holding member and the second holding arm, and the fourth elastic member is clamped between the second holding member and the second stopper.

9. A flexible display panel, comprising:
a flexible display panel main body including a flexible portion and a first portion and a second portion connected to opposite ends of the flexible portion; and
a hinge, including:
a fixed support;
a first rotation mechanism including a first transmission member rotatably connected to the fixed support;
a second rotation mechanism disposed opposite the first rotation mechanism, and including a second transmission member rotatably connected to the fixed support; and
a moving block, wherein the first transmission member and the second transmission member are movably connected to the moving block, so as to convert rotation of the first transmission member and the second transmission member to linear motion of the moving block and to drive the moving block away from or close to the fixed support;
wherein the first portion is fixedly connected to the first rotation mechanism, the second portion is fixedly connected to the second rotation mechanism, and the moving block is located under the flexible portion.

10. The flexible display panel of claim 9, wherein the first transmission member includes a first circular gear, the second transmission member includes a second circular gear, and the moving block includes a linear gear;
wherein the first circular gear and the second circular gear are meshed with the linear gear.

11. The flexible display panel of claim 10, wherein the moving block includes a base portion, the linear gear is disposed on an outside of the base portion, and the linear gear is integrally formed with the base portion.

12. The flexible display panel of claim 11, wherein the hinge further comprises a first stopper, the first stopper is mounted on the fixed support, the first stopper and the fixed support together form a first chute, and the moving block is slidably disposed in the first chute;
wherein a wall surface of the first chute is provided with a protrusion, a groove is defined by the base portion of the moving block, and the protrusion is slidably received in the groove.

13. The flexible display panel of claim 10, wherein the first rotation mechanism includes a first rotation member, and the second rotation mechanism includes a second rotation member;
wherein the first rotation member and the second rotation member are individually rotatably connected to the fixed support, the first circular gear surrounds the first rotation member, and the second circular gear surrounds the second rotation member.

14. The flexible display panel of claim 13, wherein the hinge further comprises a holding mechanism, and the holding mechanism includes a first holding arm, a second holding arm, and a first holding member, wherein the first holding member is provided with a first protrusion and a second protrusion, a first groove is defined by the first holding arm, and a second groove is defined by the second holding arm;
wherein the first holding arm is fixedly connected to the first rotation member, the second holding arm is fixedly connected to the second rotation member, and the first rotation member and the second rotation member are rotatably connected to the first holding member;
in response to the hinge being in one of an unfolded state or a folded state, the first protrusion is received in the first groove, and the second protrusion is received in the second groove; in response to the hinge being in the other state of the unfolded state or the folded state, the first protrusion is separated from the first groove, and the second protrusion is separated from the second groove.

15. The flexible display panel of claim 14, wherein the holding mechanism further includes a second holding member, the second holding member is provided with a third protrusion and a fourth protrusion, a third groove is defined by the first holding arm, and a fourth groove is defined by the second holding arm;
in response to the hinge being in one of the unfolded state or the folded state, the third protrusion is received in the third groove, and the fourth protrusion is received in the fourth groove; in response to the hinge being in the other state of the unfolded state or the folded state, the third protrusion is separated from the third groove, and the fourth protrusion is separated from the fourth groove.

16. The flexible display panel of claim 15, wherein the holding mechanism further includes a first elastic member, a second elastic member, a third elastic member, a fourth elastic member, and a second stopper;
wherein the first elastic member and the second elastic member surround the first rotation member, the first elastic member is clamped between the first holding member and the first holding arm, the second elastic member is clamped between the second holding member and the second stopper; the third elastic member and the fourth elastic member surround the second rotation member, the third elastic member is clamped between the first holding member and the second holding arm, and the fourth elastic member is clamped between the second holding member and the second stopper.

17. An electronic device, comprising a flexible display panel, and the flexible display panel including:
a flexible display panel main body including a flexible portion and a first portion and a second portion connected to opposite ends of the flexible portion; and
a hinge, including:
a fixed support;
a first rotation mechanism including a first transmission member rotatably connected to the fixed support;
a second rotation mechanism disposed opposite the first rotation mechanism, and including a second transmission member rotatably connected to the fixed support; and
a moving block, wherein the first transmission member and the second transmission member are movably connected to the moving block, so as to convert rotation of the first transmission member and the second transmission member to linear motion of the moving block and to drive the moving block away from or close to the fixed support;
wherein the first portion is fixedly connected to the first rotation mechanism, the second portion is fixedly connected to the second rotation mechanism, and the moving block is located under the flexible portion.

18. The electronic device of claim 17, wherein the first transmission member includes a first circular gear, the second transmission member includes a second circular gear, and the moving block includes a linear gear;
wherein the first circular gear and the second circular gear are meshed with the linear gear.

19. The electronic device of claim 18, wherein the moving block includes a base portion, the linear gear is disposed on an outside of the base portion, and the linear gear is integrally formed with the base portion.

20. The electronic device of claim 19, wherein the hinge further comprises a first stopper, the first stopper is mounted on the fixed support, the first stopper and the fixed support together form a first chute, and the moving block is slidably disposed in the first chute;
wherein a wall surface of the first chute is provided with a protrusion, a groove is defined by the base portion of the moving block, and the protrusion is slidably received in the groove.
